(19) United States
(12) Patent Application Publication
(10) Pub. No.: US 2006/0286807 A1
(43) Pub. Date: Dec. 21, 2006

(54) Use of active temperature control to provide emmisivity independent wafer temperature

(76) Inventors: Jack Hwang, Portland, OR (US); Robert James, Portland, OR (US); Eric J. Lambert, Beaverton, OR (US); Jonathan Leonard, Vernonia, OR (US); Richard Brindos, Hillsboro, OR (US); Karson L. Knutson, Beaverton, OR (US); Mark Armstrong, Portland, OR (US); Justin Sandford, Tigard, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/156,381

(22) Filed: Jun. 16, 2005

(51) Int. Cl. H01L 21/306; G01R 31/00; H01L 21/461

(52) U.S. Cl. 438/715; 216/59; 216/60; 156/345.24

(57) ABSTRACT

Embodiments relate to a substrate or wafer edge support having an emmisivity greater than that of a silicon wafer, where the edge support is for supporting a wafer during processing to form circuit devices on or in the wafer. Embodiments also include temperature sensors, heat conducting gas jets, and photonic energy can be directed to sense and control the temperature of the edge support and/or wafer edge during annealing to reduce temperature roll-off or roll-up at the edge as compared to the center of the wafer. Specifically, use of an edge support having an emmisivity greater than or equal to that of the wafer during processing allows helium gas jets directed at the edge support and/or wafer edge to reduce temperature roll-up at the edge during annealing. Because wafers from different processes and anneal locations may all have different emmisivities, use of the feedback loop will enable one edge ring to support the uniform anneal of wafers with a range of different emmisivities.

This application claims the benefit of the earlier filing date of non-provisional U.S. patent application Ser. No. 10/882,894, filed Jun. 30, 2004 by applicants, Jack Hwang, et al. entitled “Use of Active Temperature Control to Provide Emmisivity Independent Wafer Temperature.”

### FIELD

Manufacture of circuit devices.

### BACKGROUND

Maximizing performance and yield of circuit devices formed on a substrate (e.g., integrated circuit (IC), transistors, resistors, capacitors, etc. on a semiconductor (e.g., silicon) substrate) are major factors considered during design, manufacture, and operation of devices or equipment for manufacturing the circuit devices. It is typical for a transistor process that increasing a parameter will lead to increasing transistor performance. Beyond a critical point, the transistors will fail. The goal of transistor process engineering is to maximize performance without degrading yield. Producing the maximum number of die which meet this criteria motivates optimizing the uniformity of a process tool. For example, during design and manufacture of wafer processing chambers, such as those having thermal spike anneal capability, it is often desired to ensure that the temperature of a substrate (e.g., a wafer) being processed in the chamber remains within a desired temperature threshold. Specifically, it is desired that device or equipment for manufacture of circuit devices be capable of maintaining a uniform temperature along a substrate on which the devices are being formed, during annealing, such as during a spike annealing process.

### BRIEF DESCRIPTION OF THE DRAWINGS

Embodiments are illustrated by way of example and not by way of limitation in the figures of the accompanying drawings in which like references indicate similar elements. It should be noted that references to “an” embodiment in this disclosure are not necessarily to the same embodiment, and they mean at least one.

FIG. 1 is a cross-sectional view of a wafer processing system.

FIG. 2 is a graph plotting temperature of a wafer versus distance along the surface of the wafer for a wafer having an emmisivity greater than the emmisivity of the wafer edge support.

FIG. 3 is a graph plotting temperature of a wafer versus distance along the surface of the wafer or a wafer having an emmisivity less than the emmisivity of the wafer edge support.

FIG. 4 is a graph plotting temperature of a wafer versus the distance along the surface of the wafer for a wafer having an emmisivity equal to the emmisivity of the wafer edge support.

FIG. 5 is a flow diagram of a process for active temperature control to provide emmisivity independent wafer temperature.

### DETAILED DESCRIPTION

Various embodiments include heating and cooling apparatus, systems, and methods to heat and cool an edge or edge support of a substrate or wafer on or in which circuit devices will be formed, during thermal processing such as annealing, or spike annealing of the substrate or wafer. Embodiments also include a chamber having an edge support with a thermal mass (determined by emmisivity, mass and conductivity and heating rate) that is greater than or equal to or less than the emmisivity or thermal mass of the substrate or wafer surface. Emmisivity of a device or surface may be defined as an index of absorption of light energy represented by a range between 0 and 1, such as where an emmisivity of 0 represents a surface that reflects all light incident upon it (e.g., such as a perfect mirror) and an emmisivity of 1 represents a surface that absorbs all light incident upon it (e.g., such as a perfect black body or box). Thus, the reflectivity of a surface may be equal to 1 minus the emmisivity of that surface.

A radiation heat processing chamber is one type of wafer processing chamber utilized for thermal processing operations. In one example of a radiation heat processed chamber, an edge ring or wafer edge support (herein “edge support”) supports a substrate (e.g., a wafer) on or in which electronic circuit devices will be formed. The edge support supports the substrate about its perimeter. The rest of the wafer is unsupported.

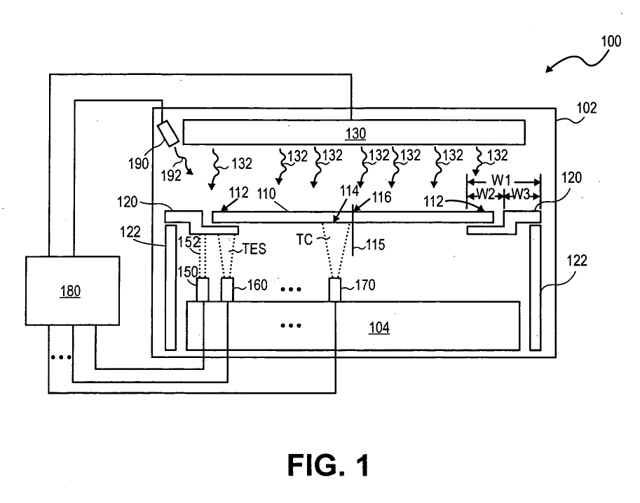

FIG. 1 is a cross-sectional view of a wafer processing system. FIG. 1 shows system 100 having wafer processing chamber 102 having an interior dimension suitable to accommodate a substrate or wafer for processing (e.g., a 150 millimeter, 200 millimeter, or 300 millimeter diameter wafer). Wafer 110 is shown in chamber 102 supported by edge support 120. According to embodiments, edge support 120 may include various appropriate materials such as silicon carbide, ceramic, silicon or other thermally stable materials that have similar emmisivity to the silicon wafer.

According to embodiments, edge support 120 may have a circular shape including a diameter greater than a diameter of a wafer intended to be processed on the edge support. In addition, edge support 120 may include a generally flat surface, such as a circular surface, with a flat circular disc shaped lip to define a seat or pocket on which a wafer intended to be processed on the edge support may be placed. For example, a cross section of edge support 120 at any point around its diameter may define an L-shaped cross section where the base of the L-shaped edge support provides a support area, such as the seat or pocket mentioned above. It is contemplated that the base of the L-shaped support may extend between one and 12 millimeters (mm) in diameter, such as by extending three mm in diameter.

Also, edge support 120 may define a cylindrical ring having an upper disc shaped step and a lower disc shaped step (e.g., where the lower disc shaped step may include the seat, pocket, or L-shaped base described above), with the upper step diameter larger than the diameter of the lower step. Moreover, the upper step may have an outer diameter to fit on, connect to, or be part of support cylinder 122. Also, the lower step may have an inner diameter less than the outer diameter of the substrate or wafer, and an outer diameter slightly larger than the outer diameter of the substrate or wafer. Thus, the lower step has a dimension suitable to support the substrate or wafer, and the upper step has a dimension suitable to support the substrate or wafer and the lower step. It is also considered the lower step may have a support lip or ring along its inner diameter to contact, touches, or support the substrate or wafer.

For some embodiments, the lower step, L-shaped base, or support lip may support the substrate or wafer by contacting or touching only a fraction of the lower or bottom surface of the substrate or wafer, such that heat transfer between the edge support and substrate or wafer is minimized. More particularly, the contacting or touching between the lower or bottom surface of the substrate or wafer and the edge support may define a contact ring having an inner diameter almost equal to its outer diameter. In addition, both the inner and outer diameter of the contact ring may be diameters between the inner and outer diameter of the lower step.

More particularly, edge support 120 may have total width W1 between two millimeters and 30 millimeters, such as by having width W1 equal to one centimeter. Similarly, edge support 120 may have edge ring support width W2 between one and 12 millimeters, such as by having width W2 equal to three millimeters. Accordingly, edge support 120 may have exposed surface width W3 between zero and 16 millimeters, such as by having width W3 equal to seven millimeters. Having a zero value for W3 would correspond to a different structure than structure 122 and 120 as shown in FIG. 1. It is also considered that, although FIG. 1 shows wafer 110 and edge support 120 having top surfaces at approximately the same height, the top surface of wafer 110 may be above, or below a top surface of edge support 120. Similarly, although the bottom or under surfaces of wafer 110 and edge support 120 are shown having a shape and difference in height in FIG. 1, various other shapes, heights, and/or orientation are possible provided edge support 120 supports wafer 110 as described herein. Moreover, edge support 120 may also include devices or features to detachably attach or connect to, support, hold down, maintain, retain or restrain wafer 110 (e.g., such as by including geometric features to reduce the sliding of the wafer,, or dislodging of the wafer from support 120, etc.)

According to embodiments, wafer 110 may be any of various types of wafers for forming electronic devices on, such as a wafer or substrate that may include, be formed from, deposited with, or grown from polycrystalline silicon, single crystal silicon, or various other suitable technologies for forming silicon base or substrate such as a silicon wafer, silicon on insulator (SOI), silicon on glass (SIOG), or other wafer or substrate formed, cut, or separated therefrom.

FIG. 1 also shows edge support 120 supported by, connected to, attached to, resting on, or part of support cylinder 122. Support cylinder 122 is connected to a drive assembly that rotates support cylinder about an axis through the center of support cylinder 122. According to embodiments, support cylinder 122, edge support 120, and wafer 110 may rotate or spin around axis 115, such as an axis defined at center 116 of disk 110. For example, wafer 110 has wafer edge 112 which may define a circle, an oval, or another bound or closed shape, such as to provide wafer 110 with a disc-like shape. In addition, edge support 120 may have a shape and/or an edge support ring that corresponds in shape to wafer edge 112, such as to support wafer edge 112 by having a circular, oval, or other bounded or closed shape. Chamber 102 includes reflector plate 104, such as a plate having a surface toward edge support 120 that is generally reflective to the light energy to which will be exposed edge support 120 and wafer 110 to maintain thermal conditions for wafer 110. Reflector plate 104 has a surface similar in size to an interior diameter of support cylinder 122, and may or may not rotate as described above with respect to spinning of wafer 110.

According to embodiments, system 100 includes heater 130 connected to, attached to or within chamber 102 to direct photonic energy 132 at wafer 110 and wafer edge support 120. According to embodiments, heater 130 may uniformly direct photonic energy with respect to the surface of wafer 110 and the surface of edge support 120. For example, heater 130 may include an array of a large number of discrete heating lamps (e.g., such as tungsten lamps) arranged in a number of zones grouped by radius (e.g., such as 14 or 15 zones) suspended above wafer 110 within chamber 102. Thus, heater 130 may be attached to a top or portion of chamber 102 that may be removed so that wafer 110 can be placed on and removed from edge support 120. It is also contemplated that chamber 102 may have an opening, door, or removable portion so that wafer 110 can be placed on and removed from edge support 120 without moving or displacing heater 130 with respect to chamber 102. Moreover, it is contemplated that the lamps of heater 130 may be focusable, such as to control the angle of divergence of the emitted light to the extent that light energy of the edge ring may be controlled without significantly impacting the temperature of the wafer. Heater 130 may be connected to a power source, power regulator, mechanism for directing or aiming photonic energy of heater 130, and/or a controller for controlling power and direction or aim of heater 130 with respect to wafer 110 and/or edge support 120.

Also, it is contemplated that heater 130 may provide sufficient heat to anneal, junction anneal, and/or spike anneal wafer 110, such as during processing or forming of electronic circuit devices on or in wafer 110. Thus, heater 130 may provide an appropriate intensity, duration, and/or focus of heat to the upper surface of wafer 110 and/or edge support 120 (e.g., such as via directed photonic energy, directed light energy, adjusting the temperature within chamber 102 and waiting for a period of time) to perform such annealing of or to electronic circuit devices on or in wafer 110. For example, heater 130 may heat wafer 110, such that location 114 or center 116 is within a selected wafer temperature change curve over a period of time corresponding to an annealing, junction annealing, and/or spike annealing process, as described herein.

System 100 may also include cooler 150 connected to, attached to or within chamber 102 in a manner to direct heat conducting gas 152 at edge support 120 and/or wafer 110 at or approximate to wafer edge 112. For example, FIG. 1 shows a simple embodiment of cooler 150 for dispensing gas 152 (e.g., such as through a hole through reflector plate 104) to direct heat conducting gas 152 at edge support 120. According to embodiments, cooler 150 may be one or more gas jets, such as helium (He) gas jets. For instance, cooler 150 may be one or more gas jets connected to one or more gas supply valves; gas supply tanks or reservoirs; mechanisms for directing, aiming or focusing the output of the jets; and/or controllers for controlling flow and direction or aim of the gas jets respect to wafer 110 and/or edge support 120. Moreover, the gas jets may have a focal point on a surface of edge ring 120 or of wafer 110 such as at or near wafer edge 112. For example, according to embodiments, cooler 150 may include between one and a large number (e.g., such as a few hundred) of jets or to be made as one continuous ring having a radius in excess of 150 mm minus W2, but less than 150 mm plus W3. The diameter of the gas jet could be less than 10 mm. The flow volume could be less than 100 liters per minute. The exact flow would depend on the diameter and the number of jets. Also, cooler 150 may include gas jets having a jet focus apparatus composed of the exact same material as the reflector plate.

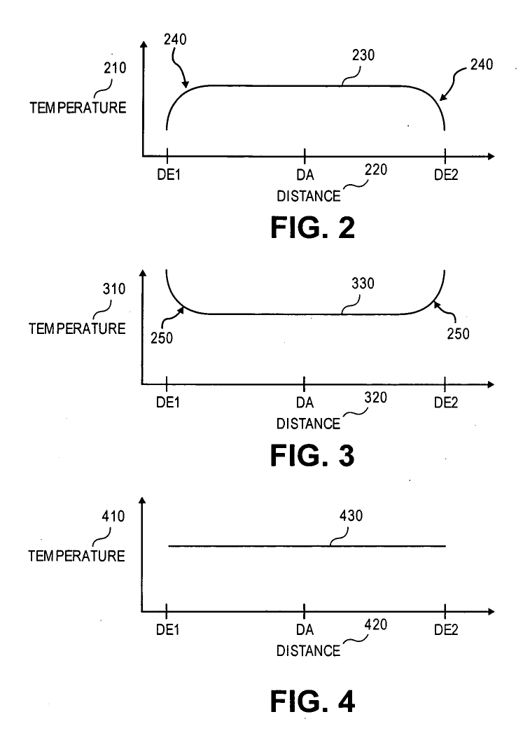

Furthermore, according to embodiments, system 100 may include a second heater connected to, attached to or within chamber 102 to direct photonic energy or other heat energy at edge support 120 and/or the surface of wafer 110 at or near wafer edge 112. For example, FIG. 1 shows heater 190 connected to or within chamber 102 to direct photonic energy 192 at edge support 120 and/or wafer edge 112. It is contemplated that heater 190 may be one or more heat lamps such as is described above with respect to heater 130. This heater can be incorporated directly into the lamphead assembly of heater 130 or as a separate unit, such as heater 190 as shown in FIG. 2. For instance, heater 190 may be moved with respect to chamber 102 during placing and removing wafer 110 from edge support 120; connected to a power source and/or regulator; connected to a mechanism for directing, aiming or focusing photonic energy of heater 130; and/or connected to a controller for controlling power and direction or aim of heater 190 with respect to wafer 110 and/or edge support 120. Specifically, heater 190 may be one or more heat lamps that are colliminated in order to concentrate the radiant energy on an area as shown by or that comprises width W1. These lamps may emit an energy density comparable to that produced by heater 130. For instance, the lamps of heater 130 and/or 190 may be grouped into radial zones for control. If the light collimation of the lamps in heater 130 were sufficient, then optimizing the selection of the individual lamps in one group that has the greatest effect on the edge ring may be sufficient. If the collimation of the lamps are not sufficient, then the lamps may use modified reflector sleeves to enable the proper collimation.

It is also to be appreciated that although cooler 150 is shown located below wafer 110 and heater 130 and heater 190 are shown above wafer 110, various other locations and orientations of the cooler and heaters with respect to wafer 110 and edge support 120 are possible. For example, cooler 150 may be located above wafer 110, heater 190 may be located below wafer 110. Moreover, heater 190, cooler 150, and/or heater 130 may be on the same side of wafer 110, such as by being above wafer 110. The exact configuration may be selected to ensure that the heater does not negatively impact the pyrometry (temperature measurement) system of the tool (e.g., such as sensors 160 and 170). In embodiments where one or more heaters are placed below the wafer and heater 130 is above the wafer, a laser system or filtered lamp system (e.g., such as at the location of heater 190) could be used to ensure that the heaters do not interfere with the detection wavelength of pyrometers (e.g., such as sensors 160 and 170).

Also note that it is contemplated that the system, apparatus, and methods described herein may apply when wafer 110 and edge ring 120 are at different temperatures other than during or after heating by heater 130. For example wafer 110 and edge ring 120 may be at different temperatures during or after heating by a heater other than heater 130 and/or 190, cooling by a cooler other than 150, internal heating or cooling of the area within chamber 102, or external heating or cooling of chamber 102.

System 100 may also include one or more temperature sensors to read the temperature of or at a surface of wafer 110 and/or edge support 120. In the case shown in FIG. 1, temperature sensor 160 connected to, attached to or within chamber 102 in a manner to measure or detect a temperature of or at a surface of edge support 120 or wafer 110 at or near wafer edge 112. Similarly, system 100 may include a temperature sensor 170 (or multiple units at different radii) connected to or within chamber 102 in a manner to measure or detect temperature TC of or at a surface of wafer 110 at location 114, such as a location of wafer 110 closer to center 116 of wafer 110 than edge support 120. In one example, there may be six other temperature sensors disposed radially between temperature sensor 160 and temperature sensor 170 so that the total number of temperature sensor is eight. Temperature sensor 160 and/or temperature sensor 170 may be a pyrometer. Also, temperature sensor 160 and/or 170 may be located on or disposed through reflector plate 104 as described above with respect to cooler 150. Likewise, temperature sensor 160 and/or 170 may be located and/or oriented with respect to wafer 110 as described above with respect to location and orientation of cooler 150. Specifically, for example, temperature sensor 160 may be located or oriented to detect the temperature of or at a surface of wafer 110 just within the radius defined by edge support 120 (e.g., such as by placing sensor 160 it at the same radius, but with an offset location since the wafer rotates). Moreover, temperature sensor 170 may be located or oriented to detect a temperature of or at a surface of wafer 110 including or at center 116.

According to embodiments, system 100 may also include a controller to measure temperatures, control heating and control cooling of wafer 110, such as a controller connected to heater 130, cooler 150, heater 190, temperature sensor 160, and/or temperature sensor 170. Specifically, FIG. 1 shows controller 180 connected or attached to temperature sensors 160 and 170, heaters 130 and 190, and cooler 150. It is to be appreciated that controller 180 may also be connected or attached to other inputs, outputs, electronic devices, controllers, and/or equipment related to system 100, such as to control or be involved in control of processing or of forming devices on or in wafer 110. For instance, controller 180 may also be connected or attached to a power source, power regulator, mechanism for directing or aiming photonic energy of heater 130. Further, controller 180 may also be connected or attached to gas supply valves; gas supply tanks or reservoirs; mechanisms for directing, aiming or focusing the output of cooler 150 and/or gas jets thereof. Finally, controller 180 may also be connected or attached to a power source and/or regulator; connected to a mechanism for directing, aiming or focusing photonic energy of heater 130.

It may be appreciated that the connections or attachments described for controller 180, temperature sensor 160, temperature sensor 170, heater 130, heater 190, cooler 150, and/or components thereof described herein may be or include an electronic interface, connection, attachment, signal line, or signal conduit. For instance, such connections or attachments may be sufficient for electronic communication or transmission of various digital or analog electronic data including via a data path, a link, a wire, a line, a printed circuit board trace, optical, infrared, and/or any of various other hard wired or free space data conduits.

Specifically, controller 180, temperature sensor 160, temperature sensor 170, heater 130, heater 190, and/or cooler 150 may be used to change the temperature of a wafer, a wafer edge, and/or an edge support during processing in chamber 100 to form devices on or in the wafer. For instance, the temperature of an edge support having an emmisivity lower than that of the wafer on the edge support, may be lower than the temperature of the wafer during or after heating via photonic energy and may conduct heat from the edge of the wafer during or after heating. As such, a wafer and an edge support may have a thermal response related to the thermal mass and the emmisivity of the wafer and edge support. Moreover, the thermal response, heating rate, and/or thermal conductivity of the wafer and edge support may differ depending on the material, thickness, emmisivity, thermal coefficient, thermal resistance, and/or thermal uniformity of the wafer being different, mismatched, or non-uniform with that of the edge support. Furthermore, since the edge support is attached to, connected to, supports, holds down, maintains, retains, restrains, or is in thermal contact with the wafer, heat transfer, such as of heat or cold, may occur between the edge support and the wafer.

In the case shown by FIG. 1, edge support 120 may have an actual or predicted heating rate dependent on a combination of the top surface emmisivity and thermal mass of edge support 120. Similarly, wafer 110 may have an actual or predicted heating rate dependent upon the top surface emmisivity and thermal mass of wafer 110. Thus, a difference between the emmisivity, thermal mass, or heating rate of edge support 120 and wafer 110 will cause the edge support and wafer to have a different temperature causing heat transfer between the edge support and the wafer edge (e.g., such as wafer edge 112) in response to exposing the edge support and wafer top surfaces to photonic energy. As a result, the temperature of wafer 110 at or near wafer edge 112 may be reduced sufficiently during an annealing process to decrease performance, yield, and/or speed of electronic devices formed at or near edge 112 of wafer 110. Specifically, those devices may include defects, imperfections, or otherwise be formed with less than optimal capabilities since those devices are not at or as close to the optimal temperature, as compared to devices closer to the center during a given process for forming the devices.

More particularly, even if an edge support is thermally calibrated to match the emmisivity of a silicon wafer during annealing or a spike anneal processing, there may be an edge temperature non-uniformity in the wafer if the wafer has a different heating rate than the edge support. This non-uniformity is likely to reduce yield or device performance for devices near the edge of the wafer. Controller 180 may receive temperature data from temperature sensors 160 and 170 to control heating and cooling of wafer 110 via heaters 130 and 190, and cooler 150. For example, controller 180 may consider data or responses from temperature sensor 160 and/or temperature sensor 170 to monitor and control heating and cooling of wafer 110 and/or edge support 120 as part of a recipe for processing or forming devices on or in wafer 110. Such a recipe may include annealing, junction annealing, spike annealing, controlling an intensity and duration of heating via heater 130, controlling an intensity duration, and/or focus of heating via heater 190, and/or controlling an intensity, duration, and/or cooling via cooler 150, cooling of wafer 110 via adjusting the temperature within chamber 102 and waiting for a period of time, a rotational speed at which wafer 110 spins, and/or various other processes related to processing of and/or forming devices in or on wafer 110, including processes described below with respect to FIG. 4.

Moreover, as described above, a surface of edge support 120, such as a top surface, may have an emmisivity that is less than, greater than, or equal to an emmisivity of a surface of wafer 110, such as the top surface of wafer 110. Subsequent descriptions will assume matched thermal masses to simplify the argument. For example, if the thermal mass of an edge ring is twice that of the wafer, the edge ring may still be cooler than the wafer even in the case where the edge support ring has higher emmisivity. The combination of the thermal mass and emmisivity is the critical parameter. The lower emmisivity of edge support 120 can cause edge support 120 to be cooler than wafer edge 112, and to conduct heat from edge 112 reducing the temperature of wafer edge 112. For example, during or after heating of wafer 110 and edge support 120 by heater 130, wafer 110 may experience a wafer edge temperature roll-off, such as by having a temperature at wafer edge 112 that is less than a temperature at location 114, when edge support 120 has an emmisivity that is lower than the emmisivity of wafer 110.

More particularly, FIG. 2 is a graph plotting temperature of a wafer versus distance along the surface of the wafer for a wafer having an emmisivity greater than the emmisivity of the wafer edge support. FIG. 2 shows temperature gradient 230 plotted with respect to temperature 210 and distance 220 along a cross-section of a wafer (e.g., such as a distance along the cross-section of wafer 110, as shown in FIG. 1). For instance, temperature gradient 230 may be a temperature gradient during heating (e.g., such as annealing or spike annealing) of wafer 110 and edge support 120 by heater 130. Moreover, temperature gradient 230 may be a temperature gradient during or after heating and/or cooling of wafer 110 and/or edge support 120 by heater 190 and/or cooler 150.

Specifically, as shown in FIG. 2, edge DE1 represents the left edge of wafer 110 (e.g., such as wafer edge 112 on the left side of wafer 110), axis DA represents center 116 of wafer 110, and edge DE2 represents the right edge of wafer 110 (e.g., such as wafer edge 112 at a point directly across wafer center 114 from DE1). Thus, FIG. 2 shows temperature gradient 230 having wafer edge temperature roll-off 240 at or near edges DE1 and DE2, such as in the case where edge support 120 has an emmisivity less than that of wafer 110, and thermally conducts heat from wafer edges DE1 and DE2 during or after heating of wafer 110 and edge support 120 by heater 130. Hence, it is contemplated that heater 190 may be used to direct photonic energy 192 towards wafer edge 112 and/or edge support 120 to remedy, reduce, correct or cure wafer edge temperature roll-off, such as roll-off 240.

Similarly, wafer 110 may experience a wafer edge temperature roll-up when edge support 120 has an emmisivity greater than that of wafer 110 (e.g., such as if the difference in emmisivity causes edge support 120 to have a temperature greater than that of wafer edge 112 and causing wafer edge 112 to conduct heat from edge support 120). Thus, during or after heating of wafer 110 and edge support 120 by heater 130, wafer 110 may experience a wafer edge temperature roll-up, such as by having a temperature at wafer edge 112 greater than the temperature at location 114.

For instance, FIG. 3 is a graph plotting temperature of a wafer versus distance along the surface of the wafer for a wafer having an emmisivity less than the emmisivity of the wafer edge support. FIG. 3 shows temperature gradient 330 plotted with respect to temperature 310 and distance 320 for a wafer (e.g., such as wafer 110) having an emmisivity less than the emmisivity of edge support 120. For example, temperature gradient 330 may be a temperature gradient during or after heating (e.g., such as annealing or spike annealing) of wafer 110 and edge support 120 by heater 130. Moreover, temperature gradient 330 may be a temperature gradient during heating and/or cooling of wafer 110 and/or edge support 120 by heater 190 and/or cooler 150.

In the case, shown in FIG. 3, since the wafer emmisivity is lower than the edge support emmisivity, the wafer may thermally conduct heat from the hotter edge support 120, thus raising the temperature of the wafer at or near edges DE1 and DE2 as compared to the temperature at axis DA. Thus, FIG. 3 shows temperature gradient 330 having wafer edge temperature roll-up 250 at or near edges DE1 and DE2, such as in the case where wafer edges DE1 and DE2 conduct heat away from edge support 120 during or after heating of wafer 110 and edge support 120 by heater 130. In this case, cooler 150 may be used to direct heat conducting gas 152 at edge support 120 and/or wafer 110 near or at wafer edge 112 to cool wafer edge 112 to remedy or reduce wafer edge temperature roll-up, such as roll-up 330.

It may also be appreciated that although FIG. 2 shows roll-off 240 similar for edge DE1 and edge DE2, the roll-off at edge DE2 may or may not be similar to that at edge DE1, such as depending on the devices or portions of devices formed at or near edges DE1 and DE2. Likewise, it is considered that temperature roll-up for edge DE2 may or may not be the same as that for edge DE1 for similar reasons.

Moreover, FIG. 4 is a graph plotting temperature of a wafer versus the distance along the surface of the wafer for a wafer having an emmisivity equal to or nearly equal to the emmisivity of the wafer edge support. For instance, FIG. 4 may show the temperature of a wafer versus distance along the surface of a wafer or a wafer having an emmisivity matched to the emmisivity of the wafer edge support. The exact tolerance for matching will depend upon the peak temperature, the heating rate, emmisivity difference and thermal mass of the wafer and edge support. Thus, FIG. 4 shows temperature gradient 430 plotted as a function of temperature 410 versus distance 420 for a wafer (e.g., such as wafer 110). FIG. 4 may be described as the case where the emmisivity of edge support 120 matches, corresponds to, equals, nearly equals, or has a solution with the emmisivity of wafer 110. Thus, in FIG. 4, no net transfer of heat will occur between wafer 110 and edge support 120 because during or after heating of the wafer and edge support via heater 130, the wafer and edge support will have the same or nearly equal temperatures as a result of having the same or nearly equal emmisivities. As noted previously, the desired case is that shown in FIG. 4 such that during processing or forming of devices on or in wafer 110, devices along the surface of wafer 110 may experience a similar thermal treatment, thus increasing performance and/or yield of those devices.

Consequently, according to embodiments of the invention, a recipe a recipe or instructions (e.g., such as instructions to be executed by a processor of a computer) for controlling processing of wafer 110, forming devices on or in wafer 110, and/or thermal treatment of wafer 110 may include heating and cooling of edge support 120 and/or wafer edge 112, such as to reduce the wafer edge temperature roll-off shown in FIG. 2 and/or wafer edge temperature roll-up shown in FIG. 3, such as to cause the wafer edge temperature to confirm or be similar to that of temperature gradient 430 as shown in and described with respect to FIG. 4.

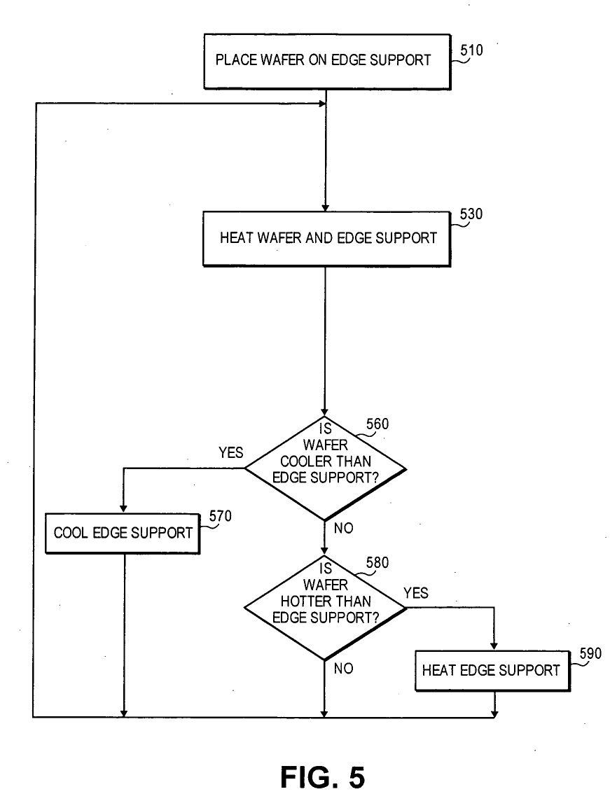

For example, FIG. 5 is a flow diagram of a process for active temperature control to provide emmisivity independent wafer temperature. According to embodiments, any or all of the blocks described below with respect to FIG. 5 may be or be included in a recipe and/or instructions (e.g., such as instructions to be executed by a processor of a computer) for forming devices or portions of devices on a wafer, as described herein (e.g., such as including annealing and/or spike annealing processes). At block 510, a wafer is placed on the edge support of a wafer processing chamber. For example, wafer 110 may be placed on edge support 120.

Wafer 110 may include partially or completely formed devices or portions of devices as described above with respect to FIG. 1 (e.g., such as transistors, resistors, capacitors, etc.). It is contemplated that wafer 110 may include film stacks, device layers, doped materials, contacts, etc. For example, processing of wafer 110 prior to block 510 may cause the emmisivity, such as the top side emmisivity, of wafer 110 to change. For example, forming devices on wafer 110 may cause the emmisivity of wafer 110 to increase.

Next, at block 530, the wafer and edge support are heated. For example, wafer 110 and edge support 120 may be heated by heater 130 during or after forming devices on the wafer, such as transistors, resistors, capacitors, etc., as described above with respect to block 510. Thus, heater 130 may expose wafer 110 and edge support 120 to photonic energy sufficient to increase the temperature of the wafer and edge support, such that if the emmisivity of the wafer is different than the emmisivity of the edge support, heat transfer may occur between the edge support and wafer edge 112 as described above. Thus, heater 130 may heat wafer 110 and wafer edge support 120 sufficiently to cause wafer edge 112 to have a temperature that is greater or less than the temperature at location 114 or center 116. Specifically, block 530 may include annealing, junction annealing, and/or a spike annealing process, such as annealing processes that may occur during process flow of processing or forming devices on or in wafer 110.

At block 530, the wafer and edge support may optionally be allowed to cool, such as by decreasing or controlling the temperature within chamber 102 and allowing time to elapse. Moreover, at block 530 heat transfer may occur between edge support 120 and wafer 110, such as between edge support 120 and wafer edge 112, as described herein. It is to be appreciated that such heat transfer may occur during or after heating of the wafer and wafer edge support as described above.

At decision block 560, it is determined whether the wafer is cooler in temperature than the edge support. For example, the measurement of temperature TC at location 114 by temperature sensor 170 may be compared with the measurement of TES by temperature sensor 160 at edge support 120 or a location of wafer 110 at or near wafer edge 112. If at decision block 560 the wafer is cooler than the edge support, the process continues to block 570 where the edge support or wafer edge is cooled. Thus, the radially outward edge of the wafer on edge support 120 may be cooled during or after heating of the wafer, such as is described above in block 530, by cooling the edge support or a surface of the wafer at or near wafer edge 112. For example, FIG. 1 shows cooler 150 to cool edge ring 120 via heat conducting gas 152. Cooling at block 570 may include cooling edge support 120 sufficiently to cause conduction of thermal energy between wafer edge 112 and edge support 120 to reduce the temperature of wafer edge 112. For example, according to embodiments, edge support 120 or wafer edge 112 may be cooled such that wafer edge 112 has a temperature equal to, within in 2° Celsius, within 5° C., within 10° C., within 15° C., or within 20° C. of the temperature of wafer 110 at location 114 or center 116. After block 570, the process returns to block 530.

If at decision block 560 the wafer is not cooler than the edge support, the process continues to decision block 580. At decision block 580 it is determined whether the wafer is hotter in temperature than the edge support. The process at block 580 for determining temperature may be similar to that described above with respect to block 560. If at block 580 it is determined that the wafer is hotter than the edge support, the process continues to block 590 where the edge support and/or wafer edge 112 are heated. For example, heater 190 may direct photonic energy 192 at edge support 120 and/or wafer edge 112 as described above with respect to FIG. 1. After block 590, the process returns to block 530.

If at block 580 the wafer is not hotter than the edge support, the process may return to block 530. Alternatively, the process may terminate such as when processing or formation of devices on or in wafer 110 is complete.

It is considered that blocks 560, 570, 580, and 590 may occur during block 530, such as to provide active temperature control during heating of the wafer and edge support. Likewise, it is to be appreciated that blocks 560 through 590 may occur after block 530, such as during cooling of the wafer and edge support over a period of time. Moreover, according to embodiments, the process shown in FIG. 5 may include blocks 560 and 570, without including blocks 580 and 590 or alternatively may include blocks 580 and 590, without including blocks 560 and 570.

Note that any or all of blocks 530 through 590 of FIG. 5 may include or be included in a feedback loop or recipe such as is described for system 100 or controller 180. Furthermore, blocks 530 through 590 may be implemented by one or more sets of computer instructions or recipes, such as to control system 100 by controller 180.

Thus, according to embodiments, system 100 or controller 180 may implement or include a recipe and/or instructions for controlling thermal treatment of wafer 110 such as by controlling heating and cooling of the wafer via heater 130, heater 190, and/or cooler 150. For example, system 100 or controller 180 may include or be capable or interpreting (e.g., such as by system 100 or controller 180 including a processor as described herein capable of interpreting machine readable instructions) a machine readable medium having data therein which when accessed by a processor (e.g., such as a computer processor, a digital signal processor, a computer, or an other hardware or software controllable device) implements a set of instructions or recipe as described herein (e.g., such as including computer software, computer instructions, or hardware circuits or logic). Thus, system 100 or controller 180 may implement instructions or a recipe to control heater 130 to heat wafer 110 such that the temperature of location 114 is within a selected wafer temperature change curve over a period of time. For example, the instructions or recipe may heat the wafer as described above with respect to block 530 of FIG. 5 and/or heat the wafer such that location 114 or center 116 is within a selected wafer temperature change curve over a period of time corresponding to an annealing, junction annealing, and/or spike annealing process. More particularly, instructions or recipe may heat wafer 110 and edge support 120 from a temperature between 150 and 700° C. for temperature stabilization that will permit the controller to activate the closed loop control (e.g., such as a temperature of 500° C.) followed by a spike phase to a temperature that increases by between 80 and 1000° C. per second (e.g., such as that increases by 200° C. per second) for between 2 and 10 seconds (e.g., such as for 5 seconds to increase the temperature of the wafer and edge support to 1000° C.) and then discontinue heating.

Similarly, system 100 or controller 180 may implement instructions or a recipe to control cooler 150 to cool edge support 120 and/or a location of 110 at or approximate to wafer edge 112 such that the temperature of the edge support or wafer edge 112 is within a selected wafer edge or edge support temperature change curve during a period of time. Thus, likewise to the description above with respect to heating via heater 130, the instructions or recipe may cause cooler 150 to direct heat conducting gas 152 towards edge support 120 and/or wafer 110 to cause the temperature of wafer edge 112 to be within a selected threshold temperature difference as compared to the temperature of wafer 110 at location 114 or center 116 during the wafer temperature change curve described above.

Similarly, system 100 or controller 180 may implement instructions or a recipe to control heater 190 to heat edge support 120 and/or a location of 110 at or approximate to wafer edge 112 such that the temperature of the edge support or wafer edge 112 is within a selected wafer edge or edge support temperature change curve during a period of time. Thus, likewise to the description above with respect to heating via heater 130, the instructions or recipe may cause heater 190 to direct photonic energy 192 towards edge support 120 and/or wafer 110 to cause the temperature of wafer edge 112 to be within a selected threshold temperature difference as compared to the temperature of wafer 110 at location 114 or center 116 during the wafer temperature change curve described above.

It is contemplated that the selected edge support, wafer edge, or radial outer edge temperature change curve may be a curve targeted to maintain the temperature of edge support 120 or wafer edge 112 to within 2° C., 5° C., 10° C., 15° C., or 20° C. of the temperature of wafer 110 at location 114 or location 116. The exact tolerance will be dictated by the process requirements. Specifically, the recipe or instructions may control heater 130, heater 190, and/or cooler 150 so that the temperature of the wafer edge (e.g., such as wafer edge 112, and/or wafer edges DE1 and DE2) do not experience temperature roll-off 240 or temperature roll-up 250, but instead that the wafer has a temperature gradient similar to that of gradient 430 shown and described with respect to FIG. 4.

For instance, system 100, controller 180, instructions, or a recipe as described herein may consider measurements from temperature sensor 160 and/or temperature sensor 170 to control heating and cooling of wafer 110 and edge support 120, such as by controlling heater 130, heater 190, and cooler 150. For example, such control may implement a feedback loop including measurements from temperature sensor 160 and temperature sensor 170 to adjust heating and cooling of wafer edge 112 via cooler 150 and heater 190. Alternatively, such control may implement a recipe or instructions, such as to control intensities and durations of heat and cooling via heater 130, heater 190, and/or cooler 150, derived from or based on trial and error tests using one or more wafers (e.g., such as wafers having various top side emmisivities) placed on one or more edge supports (e.g., such as placed on a number of edge supports similar to edge support 120 but having emmisivities) and tested within chamber 102.

Furthermore, according to embodiments, such control implementing a feedback loop or instructions based on trial and error tests may consider one or more of: an emmisivity of a wafer, an emmisivity of a wafer edge, a thermal density of a wafer edge, an emmisivity of an edge support, a thermal density of an edge support, a heating capacity of heater 130, a cooling capacity of cooler 150, a heating capacity of heater 190, a heating zone of heater 130, a cooling zone of cooler 150, and/or a heating zone of heater 190 (e.g., such as where the heating zones what portion of wafer 110 and/or edge support 120 is heated and/or cooled).

Next, according to embodiments of the invention, it is also possible to affect or control the temperature of wafer 110 with respect to edge support 120 by selecting edge support 120 having a desired actual or predicted emmisivity. Since, as explained above, the emmisivity of edge support 120 has a bearing or affect on how close the temperature of wafer edge 112 is to the temperature of location 114 or center 116 during or after heating of wafer 110 and edge support 120, it is possible to select an edge support emmisivity depending on the known (by experiment based on the edge temperature rolloff) emmisivity of wafer 110 (e.g., such as the predicted top side emmisivity or wafer 110). For a particular wavelength of 900 nm, a bare silicon wafer may have a top side emmisivity of 0.6, a wafer of silicon coated with nitride (N) may have an emmisivity of 0.9. Moreover, as noted above, the emmisivity of a wafer may increase/decrease during formation or partial formation of devices on or in the wafer. Moreover, edge support 120 may be selected having an actual or predicted emmisivity having a desired relationship with the emmisivity of the wafer after processing or formation of devices on the wafer.

For certain process flows, it is possible for the emmisivity of a silicon wafer having devices formed thereon or therein may be very different from a bare silicon wafer. Therefore, in addition to controlling heating and cooling of a wafer and edge support as described above, it is possible to select and use an edge support (e.g., such as by including the selected edge support in system 100) that has an edge support emmisivity that matches, equals, corresponds to, or is uniform with the emmisivity of or the predicted emmisivity of a wafer selected to be processed on the edge support. For example, edge support 120 may have an emmisivity that matches or equals or may have an emmisivity that provides a heating rate of edge support 120 that matches or equals the emmisivity or heating rate of wafer 110 after a portion of or all of the processing necessary to form devices on or in wafer 110. Thus, edge support 120 may have an emmisivity that is “tuned” or “uniform” with that of wafer 110 after forming the desired devices on or in wafer 110. Notably, edge support 120 may have a selected emmisivity having a relationship with the emmisivity of wafer 110 during or after forming desired devices on the wafer such that the temperature gradient along the wafer corresponds to temperature gradient 430 as shown and described with respect to FIG. 4.

In addition, the selecting of edge support 120 or determination of whether or not the emmisivity of edge support 120 matches that of wafer 110 may include considering for edge support 120 and wafer 110 one or more of “emmisivity, thermal mass, thermal conductivity, heating rate, photonic energy absorption rate, thermal response, thermal resistance, specific heat, temperature roll-off, temperature roll-up, and/or edge effect. Moreover, the selecting or matching described above may include trial and error testing to find a desired edge support emmisivity considering the processing, thermal treatment, recipe, instructions, emmisivity, device density, device type, devices and device portions to be formed on wafer 110 during the period that wafer 110 will be processed in chamber 102. Thus, edge support 120 may be selected to have an emmisivity that matches that of wafer 110 initially, at some point during processing of wafer 110, or after completion of forming devices on or in wafer 110.

In particular, according to embodiments, edge support 120 may have an emmisivity greater than or equal to or less than a predicted emmisivity of wafer 110 during or after processing of the wafer on edge support 120. Also, edge support 120 may have an emmisivity at least 2 percent, 5 percent, 10 percent, 15 percent, 20 percent, or 25 percent greater than or less than a predicted emmisivity of the top surface of wafer 110 during or after formation of device on or in wafer 110. It is also considered that edge support 120 may have an emmisivity that is greater than or equal to or less than 0.7, 0.75, 0.775, 0.8, 0.825, 0.85, 0.875, 0.9, 0.925, or 0.95. In addition, edge support 120 may have a top surface emmisivity within 10 percent of the top surface emmisivity of wafer 110 during or after forming electronic devices in or on wafer 110. The magnitude of the offset will be determined by the edge ring heater and cooler.

The complication to matching the wafer emmisivity is that he location of the anneal step in the process flow or changes to the film stack in suceeding process technologies makes the product wafer emmisivity a variable. For a particular process flow and step location, an edge support may be selected to have an actual predicted emmisivity that corresponds, equals, or has a certain relationship with the actual or predicted emmisivity of the wafer at certain points of time during processing or forming of devices or portions of devices on the wafer. If there are more than one anneal step, then it will be difficult to use one tool for the two different anneal steps if the wafer emmisivity is different at the two steps. One of the key ideas of this application is the feedback loop of the heater/cooler to enable one tool and edge ring to be capable of adapting to more than one wafer emmisivity.

Also, according to embodiments, selection of edge support 120 or matching of the emmisivity of edge support 120 with that of wafer 110 may include consideration of control, instructions, recipe, feedback loop, trial and error tests, and may include the same considerations or factors as described above with respect to instructions or recipe for system 100 or controller 180.

For example, selection of edge support 120 or matching of the emmisivity of edge support 120 with that of wafer 110 may be performed prior to including edge support 120 in chamber 102 and may be a factor in or considered during controlling of heating and cooling of wafer 110 by system 100 or controller 180 as described herein. Similarly, selection of edge support 120 or matching of the emmisivity of edge support 120 with that the wafer 110 may occur prior to block 510 of FIG. 5.

In the foregoing specification, specific embodiments are described. However, various modifications and changes may be made thereto without departing from the broader spirit and scope of embodiments as set forth in the claims. The specification and drawings are, accordingly, to be regarded in an illustrative rather than a restrictive sense.

1. A method comprising:
cooling an edge of a wafer supported by an edge support in a wafer processing device during heating of the wafer.

2. The method of claim 1, wherein cooling comprises cooling the edge of the wafer to a temperature within 10 degrees celsius of a temperature of a center of the wafer.

3. The method of claim 1, further comprising heating the wafer and the edge support sufficiently to cause heat transfer between the edge of the wafer and the edge support.

4. The method of claim 3, wherein cooling comprises cooling the edge support sufficiently to cause heat transfer between the edge of the wafer and the edge support to cool the edge of the wafer.

5. The method of claim 1, further comprising forming a plurality of devices or portions of devices on the wafer prior to heating and cooling.

6. The method of claim 5, further comprising selecting the edge support from a plurality of edge supports for use with the wafer processing device, wherein selecting comprises matching the heating rate of the selected edge support with the heating rate of the wafer.

7. The method of claim 6, wherein matching comprises considering at least one of the emmisivity, thermal mass, thermal conductivity, heating rate, photonic energy absorption rate, thermal response, thermal resistance, specific heat, temperature roll off, temperature roll up, edge effect of the edge support and of the wafer.

8. The method of claim 4, further comprising heating the edge support and the wafer with photonic energy.

9. The method of claim 8, wherein heating comprises junction annealing and spike annealing.

10. The method of claim 8, wherein heating comprises exposing the wafer and the edge support to a sufficient amount of photonic energy to cause the edge support to have a first temperature and the wafer to have a different second temperature.

11. An apparatus comprising:
an edge support having a dimension suitable to support a wafer in a processing chamber, the edge support having an emmisivity greater than or equal to a predicted emmisivity of a wafer selected for processing on the edge support.

12. The apparatus of claim 11, wherein the edge support comprises a first heating rate dependent upon the top surface emmisivity and a thermal mass of the edge support, and the wafer to have a predicted different second heating rate dependent upon the top surface emmisivity and a thermal mass of the wafer, wherein the difference between the first heating rate and the second heating rate is sufficient to cause the edge support to have a first temperature, the wafer to have a different second temperature, and a heat transfer between the edge support and the edge in response to exposing the edge support top surface and wafer top surface to photonic energy.

13. The apparatus of claim 11, further comprising a wafer supported by the edge support, wherein the edge support has a top surface emmisivity within a certain offset from the top surface emmisivity of the wafer after forming a plurality of electronic devices on the wafer. This tolerance will be determined by the capability of the edge ring heating or cooling capabilities.

14. A system comprising:
a wafer processing chamber including:
a support having an edge support and a dimension suitable to support a wafer thereon and a first emmisivity, the edge support having a different second emmisivity greater than the first emmisivity;
a heater coupled to the chamber in a manner to direct photonic energy at the wafer and the edge support;
a cooler coupled to the chamber in a manner to direct heat conducting gas at the edge support.

15. The system of claim 14, further comprising a controller coupled to the heater and the cooler to control heating of the wafer by the heating and cooling of the edge support by the cooler.

16. The system of claim 15, wherein the controller comprises a feedback loop having a first temperature sensor to measure a temperature of the edge support and a second temperature sensor to measure a temperature of a location of the wafer closer to a center of the wafer than the edge support.

17. The system of claim 14, further comprising a second heater coupled to the chamber in a manner to direct photonic energy at the edge support.

18. The system of claim 17, wherein the second heater comprises at least one heating lamp having a photonic energy focal point at the radial outer edge of the wafer. This can be either a broadband light source or a laser.

19. The system of claim 14, wherein the cooler comprises at least one helium (He) gas jet.

20. An article of manufacture comprising:
a machine-readable medium having data therein which when accessed by a processor implements a recipe to heat and cool a wafer supported by an edge support in a wafer processing device, wherein the recipe comprises:
a) controlling a first heater to heat the wafer such that a temperature of a location of the wafer closer to a center of the wafer than a radial outer edge of the wafer is within a selected wafer temperature change curve during a period of time;
b) controlling a cooler to cool the edge support such that a temperature of the edge support is within a selected edge support temperature change curve during the period of time;
c) controlling a second heater to heat the radial outer edge of the wafer such that a temperature of the radial outer edge of the wafer is within a selected radial outer edge temperature change curve during the period of time.

21. The article of manufacture of claim 20, wherein controlling the first heater, the cooler, and the second heater comprises adjusting a temperature of the radial outer edge of the wafer to a temperature within 10 degrees celsius of a temperature of the location of the wafer during the period of time.

22. The article of manufacture of claim 24, wherein controlling the first heater, the cooler, and the second heater comprises one of a feedback loop having at least two temperature sensors to measure a temperature of the edge support and a temperature of the location, and instructions derived from trail and error tests using the wafer processing device and a wafer placed on the edge support.

23. The article of manufacture of claim 20, wherein the recipe consider at least one of an emmisivity of the radial outer edge of the wafer, a thermal density of the radial outer edge of the wafer, an emmisivity of the edge support, a thermal density of the edge support, a heating capacity of the first heater, a cooling capacity of the cooler, a heating capacity of the second heater, a heating zone of the first heater, a cooling zone of the cooler, a heating zone of the second heater.
